(19) United States
(12) Patent Application Publication
(10) Pub. No.: US 2024/0099001 A1
(43) Pub. Date: Mar. 21, 2024

(54) SEMICONDUCTOR MEMORY DEVICE AND MANUFACTURING METHOD

(71) Applicant: Kioxia Corporation, Tokyo (JP)

(72) Inventor: Tadashi IGUCHI, Yokkaichi Mie (JP)

(21) Appl. No.: 18/460,506

(22) Filed: Sep. 1, 2023

(30) Foreign Application Priority Data
Sep. 9, 2022 (JP) 2022-144078

(51) Int. Cl. H10B 43/27

(52) U.S. Cl. CPC H10B 43/27

(57) ABSTRACT

According to one embodiment, a semiconductor memory device has a first film and a stacked body on the first film. The stacked body includes insulating films and conductive films stacked in a first direction. A first pillar extends through the stacked body and has a first semiconductor portion and a first insulator portion on an outer peripheral surface. A plurality of second pillars extend in the stacked body and reach the first film. The second pillars each comprise an insulator material and have a bottom surface with a protrusion protruding into the first film. A third pillar extends in the stacked body between adjacent second pillars. The third pillar comprises a conductor material that is electrically connected to one of the conductive films of the stacked body.

### CROSS-REFERENCE TO RELATED APPLICATION(S)

This application is based upon and claims the benefit of priority from Japanese Patent Application No. 2022-144078, filed Sep. 9, 2022, the entire contents of which are incorporated herein by reference.

### FIELD

Embodiments described herein relate generally to a semiconductor memory device and a manufacturing method for a semiconductor memory device.

### BACKGROUND

A semiconductor memory device, such as a NAND flash memory, may have a three-dimensional memory cell array in which memory cells are arranged three-dimensionally. In the three-dimensional memory cell array, support pillars can be provided to prevent the collapse or deflection (bending) of the memory cell array during the processing used for forming word lines of the array. In this case, in the process used for forming contacts to be connected to the word lines, the contact holes may sometimes overlap the position of the support pillars, and voids or protrusions may be generated at the bottoms of the contact holes overlapping portions of the support pillars. This may cause a short circuit between the word lines in different layers to occur via the contacts.

### BRIEF DESCRIPTION OF THE DRAWINGS

FIG. 1 is a block diagram of a semiconductor memory device according to a first embodiment.

FIG. 2 is a circuit diagram of a memory cell array of the semiconductor memory device according to the first embodiment.

FIG. 3 is a plan view showing an example of a planar layout of a part of a memory cell array of a semiconductor memory device according to a first embodiment.

FIG. 4 is a plan view showing an example of a planar layout of a part of a memory region of a semiconductor memory device according to a first embodiment.

FIG. 5 is a cross-sectional view of a memory region of a semiconductor memory device according to a first embodiment.

FIG. 6 is a cross-sectional view of a memory pillar of a semiconductor memory device according to a first embodiment.

FIG. 7 is a cross-sectional view of support pillars and contact plugs of a semiconductor memory device according to a first embodiment.

FIG. 8A is a plan view showing a positional relationship between support pillars and a contact plug of a semiconductor memory device according to a first embodiment.

FIG. 8B is a cross-sectional view showing a positional relationship between support pillars and a contact plug of a semiconductor memory device according to a first embodiment.

FIGS. 9 to 21 are cross-sectional views depicting aspects of a manufacturing method for a semiconductor memory device according to a first embodiment.

FIGS. 22 and 23 are cross-sectional views depicting aspects of a manufacturing method for a semiconductor memory device according to a second embodiment. FIG. 24 is a cross-sectional view showing a configuration example of a memory device.

### DETAILED DESCRIPTION

Embodiments provide a semiconductor memory device and a manufacturing method that prevent a short circuit and deflection of a word line of the semiconductor memory device.

In general, according to one embodiment, a semiconductor memory device includes a first film and a first stacked body on the first film. The first stacked body includes first insulating films and first conductive films alternately stacked in a first direction. A first pillar extends in the first direction in the first stacked body. The first pillar includes a first semiconductor portion and a first insulator portion on an outer peripheral surface of the first semiconductor portion. A plurality of second pillars extending in the first direction in the first stacked body and reaching the first film. The second pillars each comprise an insulator material and have a bottom surface with a protrusion part protruding into the first film. A third pillar extends in the first direction in the first stacked body between adjacent ones of the second pillars. The third pillar comprises a conductor material that is electrically connected to one of the first conductive films of the first stacked body.

Hereinafter, certain example embodiments according to the present disclosure will be described with reference to the drawings. The present disclosure is not limited to these particular examples. The drawings are schematic or conceptual, and proportions, dimensions, and the like of each aspect are not necessarily the same as actual ones. In the drawings, components substantially similar to those previously described with reference to a preceding figure are denoted by the same reference numerals, and additional description thereof may be omitted as appropriate.

### First Embodiment

### Configuration of Semiconductor Memory Device 100

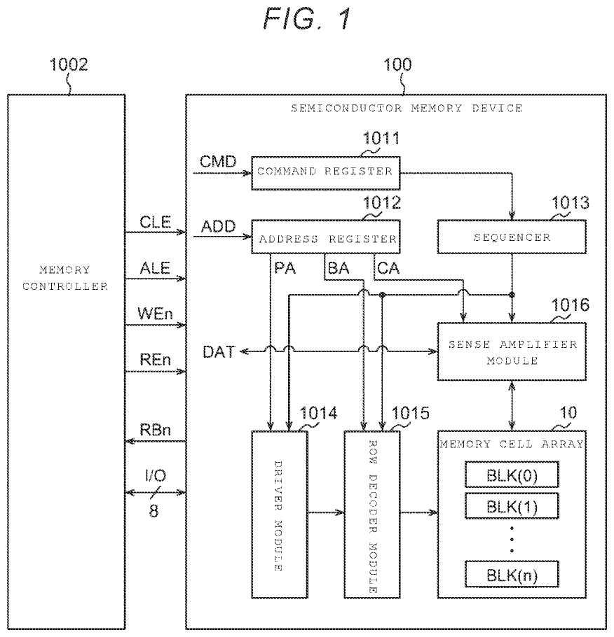

FIG. 1 is a block diagram showing a configuration example of a semiconductor memory device 100 according to a first embodiment. The semiconductor memory device 100 is, for example, a NAND flash memory capable of storing data in a nonvolatile manner. The semiconductor memory device 100 is controlled by an external memory controller 1002. Communication between the semiconductor memory device 100 and the memory controller 1002 occurs, for example, according to NAND interface standards.

As shown in FIG. 1, the semiconductor memory device 100 includes a memory cell array 10, a command register 1011, an address register 1012, a sequencer 1013, a driver module 1014, a row decoder module 1015, and a sense amplifier module 1016.

The memory cell array 10 includes a plurality of blocks BLK (BLK(0) to BLK(n)) (n is an integer of 1 or more). Each block BLK is a set of a plurality of memory cells capable of storing data in a nonvolatile manner, and is used as, for example, a data erase unit. The memory cell array 10 is provided with a plurality of bit lines and a plurality of word lines. Each memory cell is associated with one bit line and one word line.

The command register 1011 stores a command CMD received by the semiconductor memory device 100 from the memory controller 1002. The command CMD may be a command for causing the sequencer 1013 to perform a read, a write, an erase, or the like.

The address register 1012 stores address information ADD received by the semiconductor memory device 100 from the memory controller 1002. The address information ADD includes, for example, a block address BA, a page address PA, and a column address CA. For example, the block address BA, the page address PA, and the column address CA are used to select the block BLK, the word line, and the bit line, respectively.

The sequencer 1013 controls an operation of the whole semiconductor memory device 100. For example, the sequencer 1013 controls the driver module 1014, the row decoder module 1015, the sense amplifier module 1016, and the like based on the command CMD stored in the command register 1011 to read, write, or erase data or the like.

The driver module 1014 generates a voltage used to read, write, or erase data or the like. For example, the driver module 1014 applies the generated voltage to a signal line corresponding to the selected word line based on the page address PA stored in the address register 1012.

The row decoder module 1015 includes a plurality of row decoders. Each of the row decoders selects one block BLK in the corresponding memory cell array 10 based on the block address BA stored in the address register 1012. For example, the row decoder transfers the voltage applied to the signal line corresponding to the selected word line to the selected word line in the selected block BLK.

In the write operation, the sense amplifier module 1016 applies a desired voltage to each bit line according to write data DAT received from the memory controller 1002. In the read operation, the sense amplifier module 1016 determines data stored in a memory cell based on the voltage of the bit line, and transfers the determination result to the memory controller 1002 as read data DAT.

The semiconductor memory device 100 and the memory controller 1002 may be combined together to constitute one, integrated semiconductor device. Examples of such a semiconductor device include a memory card, such as an SD™ card, and a solid-state drive (SSD).

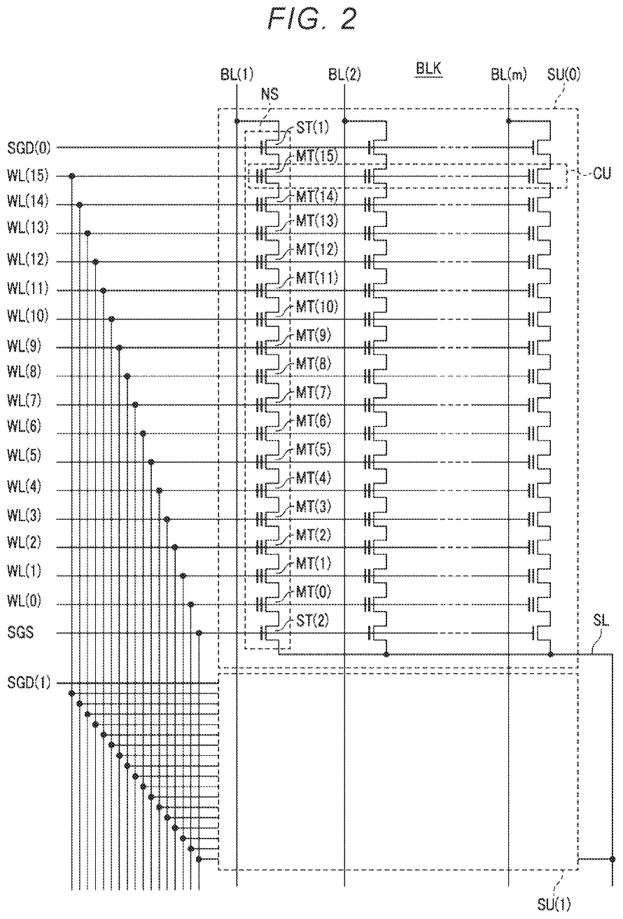

FIG. 2 is a circuit diagram showing an example of a circuit configuration of the memory cell array 10. One block BLK is depicted from the plurality of blocks BLK provided in the memory cell array 10 as representative. As shown in FIG. 2, the block BLK includes a plurality of string units SU(0) to SU(k) (k is an integer of 1 or more).

Each string unit SU includes a plurality of NAND strings NS respectively associated with bit lines BL(0) to BL(m) (m is an integer of 1 or more). Each NAND string NS includes memory cell transistors MT(0) to MT(15) and select transistors ST(1) and ST(2). Each of the memory cell transistors MT includes a control gate and a charge accumulation layer and stores the data in a nonvolatile manner. Each of the select transistors ST(1) and ST(2) is used to select a string unit SU in various operations.

In each NAND string NS, the memory cell transistors MT(0) to MT(15) are connected in series. The drain of the select transistor ST(1) is connected to the associated bit line BL, and the source of the select transistor ST(1) is connected to one end of the memory cell transistors MT(0) to MT(15) connected in series. The drain of the select transistor ST(2) is connected to the other end of the memory cell transistors MT(0) to MT(15) connected in series. The source of the select transistor ST(2) is connected to a source line SL.

In the same block BLK, the control gates of the memory cell transistors MT(0) to MT(15) are respectively connected to word lines WL(0) to WL(15). The gates of the select transistors ST(1) in the string units SU(0) to SU(k) are connected to the select gates SGD(0) to SGD(k). The gates of the select transistors ST(2) are connected to a select gate line SGS.

In the circuit configuration of the memory cell array 10, a bit line BL is shared by the NAND strings NS assigned the same column address in each string unit SU. The source line SL can be shared by a plurality of blocks BLK.

A set (group) of memory cell transistors MT connected to a common word line WL in one string unit SU can be referred to as a cell unit CU. For example, the storage capacity of a cell unit CU including the memory cell transistors MT (each storing one bit of data) may be defined as “one page of data”. In some examples, a cell unit CU may have a storage capacity of two pages of data or more according to the number of bits of data that can be stored in each individual memory cell transistors MT.

The memory cell array 10 provided in the semiconductor memory device 100 according to the present embodiment is not limited to the circuit configuration described above. For example, the numbers of the memory cell transistors MT and the select transistors ST(1) and ST(2) provided in each NAND string NS may be any numbers. The number of string units SU provided in each block BLK may be any number.

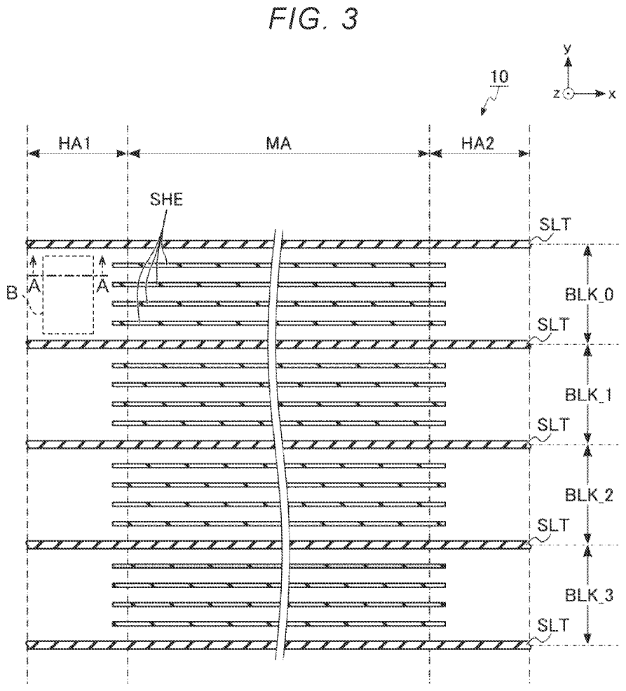

FIG. 3 is a plan view showing an example of a planar layout of a part of the memory cell array 10 of the semiconductor memory device 100 according to the first embodiment. FIG. 3 shows a region along an xy plane in which four blocks BLK 0 to BLK 3 are formed. The structure shown in FIG. 3 is typically repeatedly provided along the y-axis direction.

As shown in FIG. 3, the memory cell array 10 includes a memory region MA, a lead-out region HA1, and a lead-out region HA2. The lead-out region HA1, the memory region MA, and the lead-out region HA2 are arranged in this order along an x-axis direction. The memory cell array 10 is provided with a plurality of slits SLT and a plurality of slits SHE.

The memory region MA includes therein a plurality of NAND strings NS. The lead-out region HA1 and the lead-out region HA2 are regions provided with contact plugs connected to a stacked structure in which the memory cell transistors MT are formed.

The slits SLT extend along the x-axis and are arranged apart from each other along the y-axis. Each slit SLT is located at a boundary between adjacent blocks BLK. The slit SLT crosses the memory region MA, the lead-out region HA1, and the lead-out region HA2. Each slit SLT can have a structure in which an insulator or a plate-shaped contact surrounded by insulator is embedded. Each slit SLT divides adjacent stacked structures.

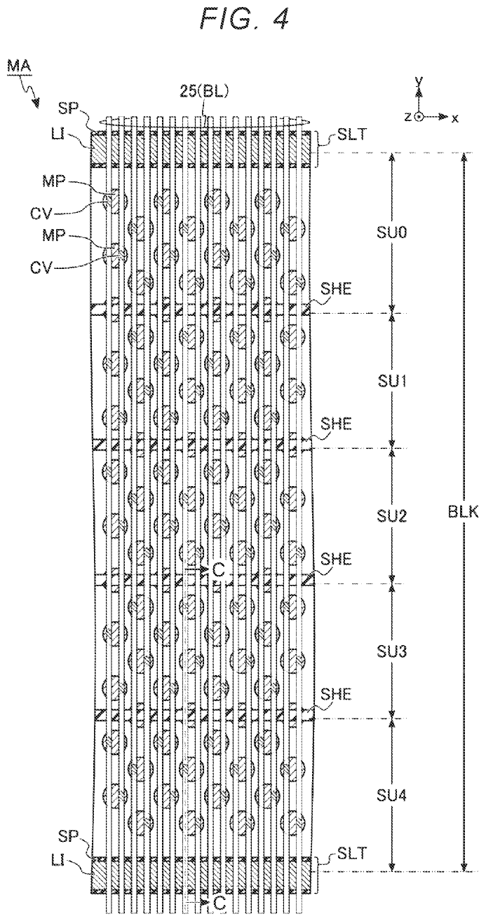

The slits SHE extend along the x-axis and are arranged apart from each other along the y-axis. Each slit SHE is located between two otherwise adjacent slits SLT. FIGS. 3 and 4 show an example of four slits SHE between each pair of slits SLT. Each slit SHE crosses the memory region MA along the x-axis direction. The opposite ends of each slit SHE are located in the lead-out region HA1 and the lead-out region HA2, respectively. Each slit SHE includes, for example, an insulator. Each slit SHE divides the adjacent select gate lines SGDL. Each region divided by the slit SLT and the slit SHE is a region in which one string unit SU is formed.

FIG. 4 is a plan view showing an example of a planar layout of a part of the memory region MA of the semiconductor memory device 100 according to the first embodiment. FIG. 4 shows one block BLK, that is, a region including the string units SU0 to SU4, and the two slits SLT sandwiching the block BLK. As shown in FIG. 4, the memory cell array 10 includes a plurality of memory pillars MP, a plurality of contact plugs CV, and a plurality of conductors 25 in the memory region MA. In this example, each slit SLT includes a contact L1 and a spacer SP.

Each of the memory pillars MP has a structure by which a memory cell transistor MT can be formed. The memory pillar MP is an example of a first pillar. The memory pillar MP includes one or more of a semiconductor, a conductor, and an insulator. Each memory pillar MP functions as one NAND string NS. The plurality of memory pillars MP are distributed in a staggered arrangement in the region between the two slits SLT. The memory pillars MP are arranged in a plurality of columns extending along the y-axis direction. In this example, each column each column includes two sub-columns of memory pillars MP arranged along the y-axis direction, but with memory pillars in adjacent sub-columns being offset from each other in the y-axis direction so as not to overlap with each other along the x-axis direction. A coordinate on the y-axis of each of the memory pillars MP in one of the sub-columns is located at a coordinate on the y-axis between two adjacent memory pillars MP in the other sub-column. Each column (of two sub-columns) includes, for example, twenty-four (24) memory pillars MP.

The slits SHE overlap, for example, the fifth, tenth, fifteenth, and twentieth memory pillars MP along the column direction as counted from the top of FIG. 4.

Each conductor 25 functions as one bit line BL. The conductors 25 extend along the y-axis and are arranged apart from one another along the x-axis. Each conductor 25 overlaps at least one memory pillar MP for each string unit SU. FIG. 4 shows an example in which a pair of conductors 25 overlap each memory pillar MP. However, each memory pillar MP is electrically connected to just one conductor 25 of the conductors 25 overlapping the memory pillar MP via a contact plug CV.

The contact L1 is made of a conductor material. The contact L1 extends along an xz plane and has a plate-like shape. The spacer SP is an insulator and is located on a side surface of the contact L1, for example, covers the side surfaces of the contact L1.

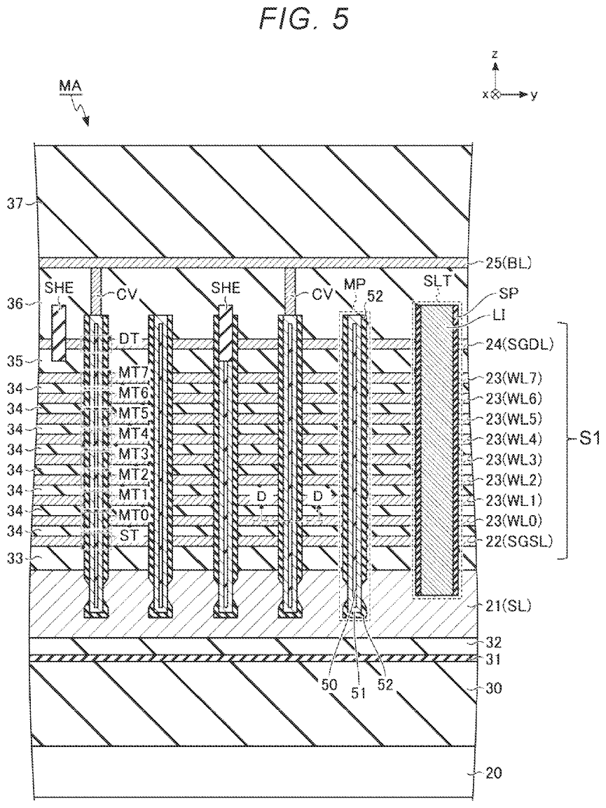

FIG. 5 is a cross-sectional view showing a cross-sectional structure of a part of the memory region MA of the semiconductor memory device 100 according to the first embodiment. FIG. 5 is a cross-sectional view taken along a line CC shown in FIG. 4.

As shown in FIG. 5, the memory cell array 10 includes a substrate 20, a conductor 21, a conductor 22, a plurality of conductors 23, a conductor 24, a conductor 25, and insulators 30, 31, 32, 33, 34, 35, 36, and 37. FIG. 5 shows an example with eight layers of conductors 23. Except for the insulator 31, insulators 30 to 37 can be an insulator material such as silicon oxide. The insulator 31 may be another insulator material, such as silicon nitride (SiN), different from the others.

The substrate 20 is, for example, a p-type semiconductor substrate. The insulator 30 is located on an upper surface of the substrate 20. A circuit including various circuit elements is formed in the substrate 20 and the insulator 30. The circuit includes, for example, the command register 1011, the address register 1012, the sequencer 1013, the driver module 1014, the row decoder module 1015, and the sense amplifier module 1016, and further includes a transistor or the like.

The insulator 31 is located on an upper surface of the insulator 30. For example, the insulator 31 prevents penetration of hydrogen into the transistors and the like provided in the substrate 20 and the insulator 30 from the structure formed above the insulator 31.

The insulator 32 is located on an upper surface of the insulator 31.

The conductor 21 is located on an upper surface of the insulator 32. The conductor 21 is an example of a conductive material film. The conductor 21 extends along the xy plane and has a generally plate-like shape. The conductor 21 functions as at least a part of the source line SL. The conductor 21 can be or comprise silicon doped with phosphorus (P).

The insulator 33 is located on an upper surface of the conductor 21.

The conductor 22 is located on an upper surface of the insulator 33. The conductor 22 extends along the xy plane and has a generally plate-like shape. The conductor 22 functions as a part of the select gate line SGSL. The conductor 22 comprises, for example, tungsten (W).

The plurality of insulators 34 and the plurality of conductors 23 are alternately located one by one along a z-axis on an upper surface of the conductor 22. The insulators 34 are an example of first insulating films, and the conductors 23 are an example of first conductive films. The z axis is an example of a first direction. A stacked body S1 is obtained by alternately stacking the plurality of insulators 34 and the plurality of conductors 23 along the z-axis direction. The stacked body S1 is an example of a first stacked body. In the stacked body S1, the conductors 23 are separated apart from each other or are arranged along the z axis at intervals. The insulators 34 and the conductors 23 extend along the xy plane and have a plate-like shape. As depicted, the plurality of conductors 23 function as the word lines WL0 to WL7 in order from the substrate 20. The conductor 23 comprises, for example, tungsten.

The insulator 35 is located on an upper surface of the uppermost conductor 23.

The conductor 24 is located on an upper surface of the insulator 35. The conductor 24 extends along the xy plane and has a plate-like shape. The conductor 24 functions as at least a part of the select gate line SGDL. The conductor 24 includes tungsten.

The insulator 36 is located on an upper surface of the conductor 24.

The conductor 25 is located on an upper surface of the insulator 36. The conductor 25 has a linear shape and extends along the y-axis direction. The conductor 25 functions as at least a part of one bit line BL. The conductor 25 is also provided on a yz plane different from the yz plane shown in FIG. 5, and thus the conductors 25 are arranged at intervals along the x-axis. The conductor 25 comprises, for example, copper.

The insulator 37 is located on an upper surface of the conductor 25.

Each memory pillar MP extends along the z-axis direction and has a columnar shape. The memory pillar MP is an example of a first pillar. The memory pillar MP extends in the z-axis direction in the stacked body S1. An upper surface of the memory pillar MP is located above the conductor 24. A lower surface of the memory pillar MP is located in the conductor 21. A portion where the memory pillar MP and the conductor 22 are in contact with each other functions as the select gate transistor ST. A portion where the memory pillar MP and one conductor 23 are in contact with each other functions as one memory cell transistor MT. A portion where the memory pillar MP and the conductor 24 are in contact with each other functions as a select transistor DT.

The memory pillar MP comprises, for example, a core 50, a semiconductor film 51, and a stacked film 52. The core 50 is made of an insulator such as, for example, silicon oxide. The core 50 extends along the z-axis direction and has a columnar shape. The semiconductor film 51 comprises, for example, silicon. The semiconductor film 51 is an example of a first semiconductor portion. The semiconductor film 51 covers an outer surface of the core 50. The stacked film 52 covers a lower end surface and a part of a side surface of the semiconductor film 51. The stacked film 52 is an example of a first insulator portion. The stacked film 52 has an opening (gap) in its coverage of the semiconductor film 51 within the conductor 21. The conductor 21 extends into the opening in the stacked film 52. The conductor 21 and the semiconductor film 51 contact each other via the opening.

As described above, one memory pillar MP and one conductor 25 are connected by the contact plug CV.

The slit SLT divides the conductors 22 to 24. An upper surface of the slit SLT is located above the upper surface of the memory pillar MP. A lower surface of the contact L1 is in contact with the conductor 21. The spacer SP is located between the contact L1 and the conductors 22 to 24, and insulates the contact L1 from the conductors 22 to 24. The contact L1 functions as a part of the source line SL.

The slits SHE divide the conductor 24. A lower surface of each of the slits SHE is positioned in the insulator 35. The slit SHE includes, for example, an insulator such as silicon oxide.

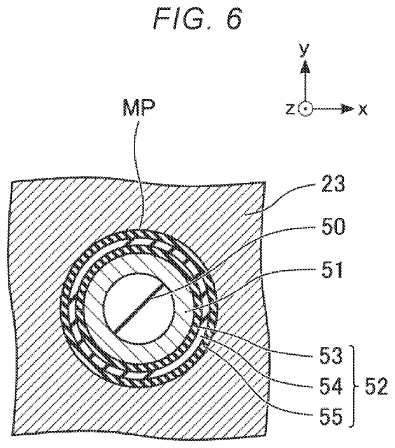

FIG. 6 shows a cross-sectional structure of the memory pillar MP of the semiconductor memory device 100 according to the first embodiment. FIG. 6 shows a cross section taken along a line BB shown in FIG. 5. As shown in FIG. 6, the stacked film 52 includes, for example, a tunnel insulating film 53, a charge storage film 54, and a block insulating film 55.

The tunnel insulating film 53 covers an outer periphery of the semiconductor film 51. The charge storage film 54 covers an outer periphery of the tunnel insulating film 53. The block insulating film 55 covers an outer periphery of the charge storage film 54. The conductor 23 covers an outer periphery of the block insulating film 55.

The semiconductor film 51 functions as a channel (current path) of the select transistors DT and ST along with the memory cell transistors MT0 to MT7. Each of the tunnel insulating film 53 and the block insulating film 55 includes, for example, silicon oxide. The charge storage film 54 stores charges. The charge storage film 54 includes, for example, silicon nitride.

### Description of Support Pillars HR and Contact Plugs CC

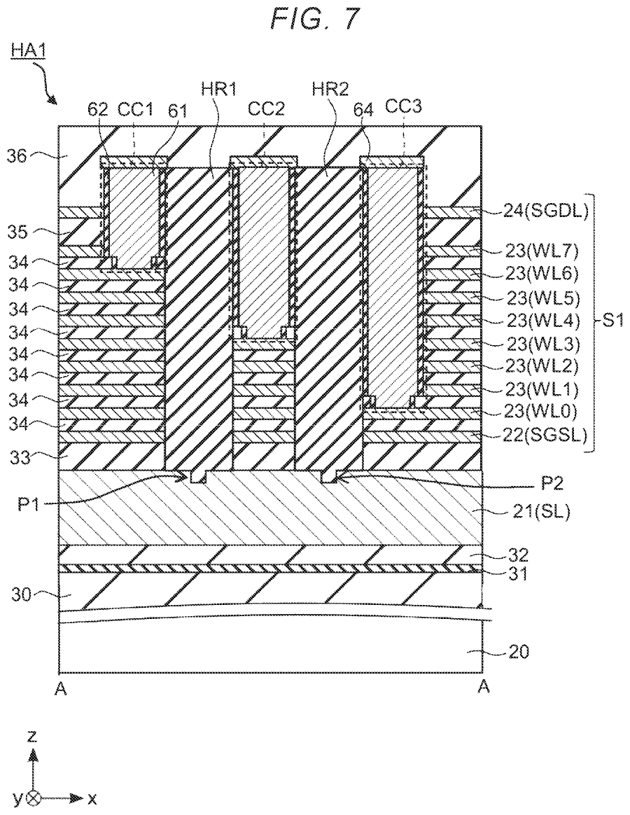

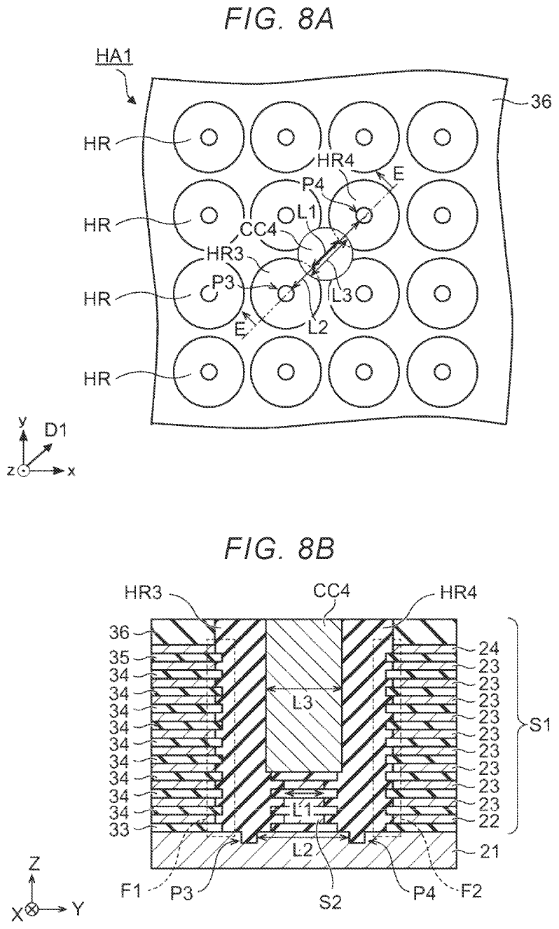

Here, the support pillars HR and the contact plugs CC will be described in detail with reference to FIGS. 7 to 8B.

FIG. 7 is a cross-sectional view showing a configuration example of the support pillars HR and the contact plugs CC. FIG. 7 is a cross-sectional view taken along a line AA shown in FIG. 3.

FIGS. 8A and 8B are a plan view and a cross-sectional view showing a positional relationship between the support pillars HR and the contact plug CC. FIG. 8A is a plan view obtained by enlarging a region B shown in FIG. 3, and FIG. 8B is a cross-sectional view taken along a line EE shown in FIG. 8A.

The support pillars HR1 to HR4 and the contact plugs CC1 to CC4 shown in FIGS. 7 to 8B have the same configuration. Hereinafter, the support pillars HR1 to HR4 may be collectively referred to as support pillars HR, and the contact plugs CC1 to CC4 may be collectively referred to as contact plugs CC.

Each of the contact plugs CC extends out from the stacked body S1 along the z-axis direction. The contact plug CC is an example of a third pillar. The contact plug CC includes conductors 61 and 64 and a spacer 62. The contact plug CC includes a columnar conductor 61. An outer periphery of the conductor 61 is covered with the spacer 62. An upper surface of the conductor 61 is covered with the conductor 64. Each contact plug CC is provided between adjacent support pillars HR. For example, the contact plug CC2 is provided between the support pillar HR1 and the support pillar HR2 which are adjacent to each other. The contact plugs CC and the support pillars HR may be in contact with or separated from each other. Any number of contact plugs CC may be provided in the lead-out region HA1.

The conductor 61 has, on a lower surface thereof, a protrusion directed downward in the z-axis direction. The protrusion is in contact with an upper surface of one conductor 23. Accordingly, each of the contact plugs CC is electrically connected to one conductor 23. For example, as shown in FIG. 7, a lower surface of the contact plug CC1 is in contact with the upper surface of the conductor 23 functioning as the word line WL6. A lower surface of the contact plug CC2 is in contact with the upper surface of the conductor 23 functioning as the word line WL3. A lower surface of the contact plug CC3 is in contact with an upper surface of the conductor 23 functioning as the word line WL0.

The spacer 62 covers a side surface of the conductor 61. The spacer 62 is an example of a second insulating film. The spacer 62 is, for example, silicon oxide. As shown in FIG. 7, a side surface of the spacer 62 of the contact plug CC1 is in contact with the conductors 23 and 24 and the insulators 35 and 36. The spacer 62 of each of the contact plugs CC2 and CC3 is further in contact with one or more conductors 23 and one or more insulators 34. The conductor 61 is insulated, by the spacer 62, from the conductors 23 other than the conductor 23 in contact with the lower surface of the conductor 61. Therefore, the contact plugs CC can not be erroneously connected to the conductors 23.

The conductor 64 covers the upper surface of the conductor 61 and is electrically connected to the conductor 61.

The support pillars HR extend out from the stacked body S1 along the z-axis direction. The support pillars HR are an example of second pillars. The support pillars HR function as support pillars that prevent a collapse of the stacked body S1 (memory cell array 10) in a replacement process used in a later stage of manufacturing. The support pillars HR are required to be provided at intervals of a predetermined value or less (the minimum interval that can prevent collapse). The support pillars HR each have a columnar shape and extend along the z-axis from the insulator 36 to the conductor 21. A part (protruding portions P1, P2, P3 . . . ) of a bottom surface of the support pillar HR may protrude toward the conductor 21. The protruding portion P1 protrudes from a bottom surface of the support pillar HR1 toward the conductor 21. The protruding portion P2 protrudes from a bottom surface of the support pillar HR2 toward the conductor 21. The support pillar HR is made of an insulator such as silicon oxide. Therefore, the protruding portions P1 and P2 are also made of an insulator such as silicon oxide. Any number of support pillars HR may be provided in the lead-out region HA′.

As shown in FIG. 8A, the support pillars HR are provided at intervals of the predetermined value or less over the entire lead-out region HA′. FIG. 8A also depicts positions for the protruding portions P3, P4 and the like on the lower surface of the support pillars HR. For convenience of description, only one contact plug CC4 is shown. The contact plug CC4 and the support pillars HR3 and HR4 each have a substantially circular planar shape. However, in a plan view in the z direction, the contact plug CC4 may partially overlap the support pillars HR3 and HR4 while maintaining a substantially circular shape. Accordingly, an outer periphery of each of the support pillars HR has a shape with an arc part or a plurality of arc parts cut out therefrom.

The support pillars HR3 and HR4 are formed by etching the stacked body S1 isotropically from positions of the protruding portions P3 and P4 in the xy plane. Therefore, the protruding portions P3 and P4 are located substantially at centers of the bottom surfaces of the support pillars HR3 and HR4 (centers of the circles), respectively.

As shown in FIG. 8B, an outer edge of the contact plug CC4 protrudes from outer edges of the support pillars HR3 and HR4 toward a respective central axis of the support pillars HR3 and HR4 by the contact plug CC4 partially overlapping the support pillars HR3 and HR4. In a portion of the stacked body S1 below the contact plug CC4 (portion between the contact plug CC4 and the conductor 21), the outer edges of the support pillars HR3 and HR4 protrude from the outer edge of the contact plug CC4 toward a central axis of the contact plug CC4. Therefore, a portion S2 of the stacked body S1 that is constricted more than the contact plug CC4 is provided below the contact plug CC4.

Here, distances L1, L2, L3 will be described. As depicted in FIG. 8A, the distances L1 to L3 are widths (distances) in a D1 direction in the xy plane. The distance L1 is a width of the portion S2 of the stacked body S1 below the contact plug CC4, and is the interval between the support pillar HR3 and the support pillar HR4 adjacent to each other (interval between the outer edges of HR3 and HR4) below the contact plug CC4. The distance L2 is the interval between the protruding portion P1 and the protruding portion P2 adjacent to each other in the D1 direction (interval between outer edges of P3 and P4). The distance L3 is a diameter of the contact plug CC4 and is the interval between the support pillar HR3 and the support pillar HR4 adjacent to each other (interval between the outer edges of HR3 and HR4) in a region within the contact plug CC4. The distances L1, L2, L3 may also be referred to as intervals L1, L2, L3, respectively.

Holes for the support pillars HR3 and HR4 are initially formed in the stacked body S1 in the z direction according to the positions of the protruding portions P3 and P4 according to the sizes (diameters) of the protruding portions P3 and P4, and are then expanded to the sizes of the support pillars HR3 and HR4 by etching the support pillars HR3 and HR4 outwardly in an xy direction by isotropic etching. In a plan view viewed from the z direction, the interval L2 between the protruding portions P3 and P4 is larger than the interval L3 (diameter of the contact plug CC4) between the support pillars HR3 and HR4 at a position of the contact plug CC4. The interval L1 between the support pillars HR3 and HR4 below the contact plug CC4 is narrower than the interval L3.

Since the interval L2 is larger than the interval L3, the protruding portions P1 and P2 do not overlap the contact plug CC4. However, since the interval L1 is narrower than the interval L3, the support pillars HR3 and HR4 overlap the contact plug CC4 in the plan view as viewed from the z direction. That is, in the step of forming the support pillars HR3 and HR4, the holes for the support pillars HR3 and HR4 are formed at a relatively wide interval L2 so as not to overlap the contact plug CC4 in the plan view as viewed from the z direction, and are then expanded to the interval L1 (or L3). The expanded holes for the support pillars HR3 and HR4 expose a side surface of the contact plug CC4 and narrow the width of the portion S2 of the stacked body S1 below the contact plug CC4.

In an eventual replacement process (described below), the support pillars HR arranged at the interval of the distance L2 cannot by themselves reliably support the stacked body S1 and thus the stacked body S1 may collapse or bend (deflect). However, when the support pillars HR having the sizes of the protruding portions P3 and P4 are densely arranged at the interval L3 or less, it is required to simultaneously etch not only the stacked body S1 but also the support pillars HR during formation of the contact plug CC4. In this case, a void may be generated in a bottom portion of the contact hole due to excessive etching of the support pillars HR, or alternatively, the support pillars HR may protrude from the bottom portion of the contact hole due to insufficient etching.

In contrast, in the present embodiment, holes corresponding to the protruding portions P3 and P4 arranged at the relatively wide interval L2 are expanded in the xy plane and become holes for the support pillars HR3 and HR4 arranged at the relatively narrow interval L1 or L3. In the subsequent replacement process, the support pillars HR3 and HR4 (each formed by embedding an insulating film in such a corresponding hole) can reliably support the stacked body S1 and can prevent collapse or deflection of the stacked body S1.

The formation of the contact hole of the contact plug CC4 can be performed either during or before formation of the holes having the sizes of the protruding portions P3 and P4. Since the protruding portions P3 and P4 do not overlap the contact plug CC4 in the plan view as viewed from the z direction, the formation of the contact hole of the contact plug CC4 does not require simultaneously processing the stacked body S1 and the support pillars HR. Therefore, it is possible to prevent the generation of the void in the bottom portion of the contact hole or remaining of the protrusion.

During the expansion of the holes for the support pillars HR3 and HR4 by the isotropic etching, as shown in regions F1 and F2, the insulators 33 to 35 may protrude from the outer edges of the support pillars HR3 and HR4 toward the central axes of the support pillars HR3 and HR4.

FIGS. 8A and 8B show the contact plugs CC4 and the support pillars HR3 and HR4, and the same applies to the other contact plugs CC1 to CC3, the other support pillars HR1 and HR2, and the like. FIGS. 7 to 8B show the support pillars HR and the contact plugs CC in the lead-out region HA′ (shown in FIG. 3), and the support pillars HR and the contact plugs CC may be formed in the same manner in the lead-out region HA2.

### Manufacturing Method for Semiconductor Memory Device 100

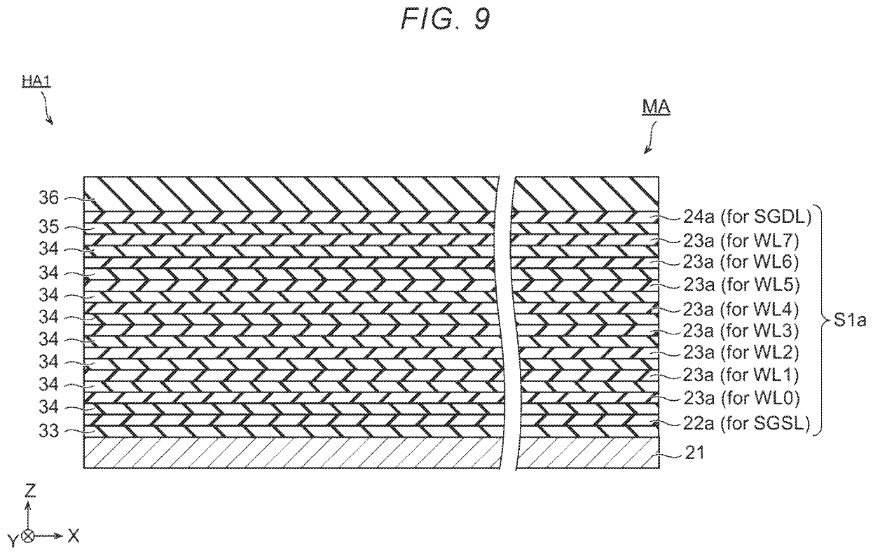

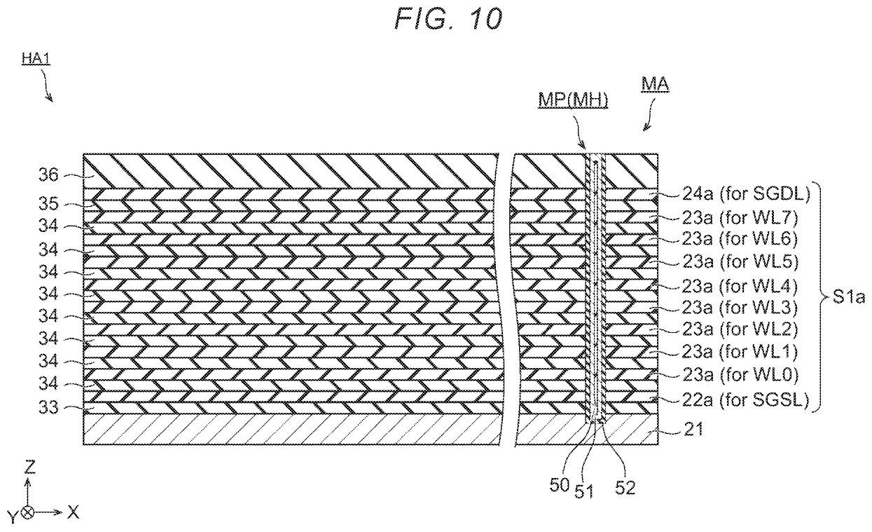

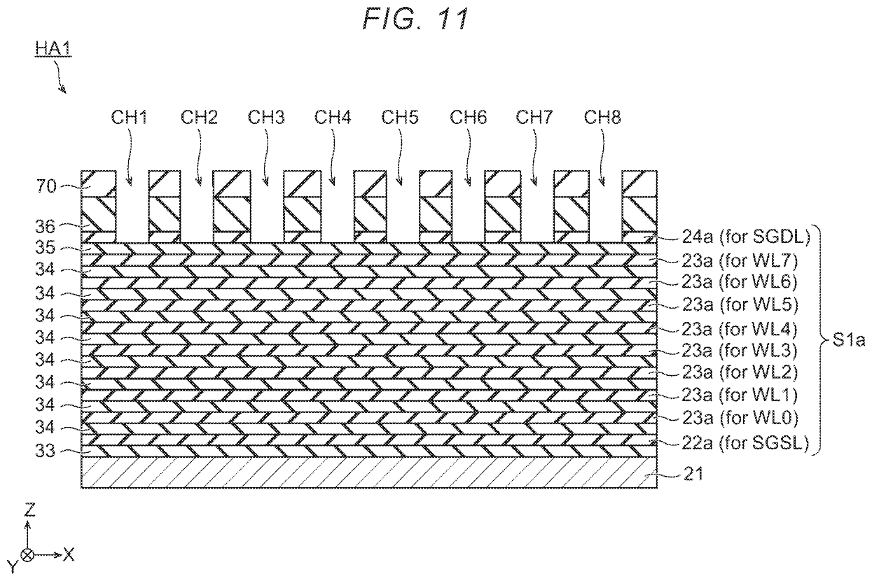

FIGS. 9 to 21 are cross-sectional views for explaining steps of the manufacturing method for the semiconductor memory device 100 according to the first embodiment. FIGS. 9 and 10 show the lead-out region HA1 and the memory region MA, and FIGS. 11 to 21 show the lead-out region HA1.

First, as shown in FIG. 9, a stacked body 1a is formed by alternately stacking sacrificial films 22a to 24a and the insulators 33 to 36 in the z-axis direction on the conductor 21. Examples of the conductor 21 include a conductive material such as a silicon substrate (silicon single crystal) or doped polysilicon. The sacrificial films 22a to 24a are examples of first sacrificial films. Examples of the insulators 33 to 36 include a silicon oxide film, and examples of the sacrificial films 22a to 24a include a silicon nitride film. The substrate 20 and the insulators 30 to 32 are formed below the conductor 21 (see FIG. 5).

Next, as shown in FIG. 10, the memory pillar MP is formed in the memory region MA. Specifically, in the memory region MA, a memory hole MH is formed by photolithography and anisotropic etching. The memory hole MH is formed in a region where the memory pillar MP is to be formed. The memory hole MH penetrates the insulators 33 to 36, the sacrificial films 22a to 24a, and the conductor 21. A bottom of the memory hole MH is located in the conductor 21. The stacked film 52 (that is, the tunnel insulating film 53, the charge storage film 54, and the block insulating film 55) are formed on an inner wall of the memory hole MH. The semiconductor film 51 is formed on an inner surface of the stacked film 52. The core 50 is formed on an inner surface of the semiconductor film 51, such that the center of the memory hole MH is filled by the core 50. Thereafter, an upper portion of the core 50 is removed, and another portion of the semiconductor film 51 is formed on the removed portion at the upper end of the memory hole MH. The memory pillar MP is formed to extend in the z-axis direction in the stacked body Sla. Any number of memory pillars MP may be formed.

Next, contact holes CH1 to CH8 for the contact plugs CC are formed by the processes shown in FIGS. 11 to 15. In FIGS. 11 to 21, the lead-out region HA1 is shown, but the memory region MA is not shown. Hereinafter, any or all of the contact holes CH1 to CH8 may be referred to as contact holes CH. The contact holes CH are an example of first contact holes. As described with reference to FIG. 7, the plurality of contact plugs CC are formed at a depth corresponding to the positions of the conductors 23 with which the contact plugs CC are in contact. That is, bottom surfaces of the plurality of contact plugs CC are formed in a stepped shape to be located at different heights. Accordingly, the contact plugs CC are electrically connected to the corresponding conductor 23 (word line WL), and can apply a desired voltage to the conductors 23. Accordingly, the contact holes CH are also formed at different depths. That is, bottom surfaces of the contact holes CH are also formed in a stepped shape to be located at different heights.

In order to make the depths of the plurality of contact holes CH different from each other in this manner, lithography and etching are used. In order to form the contact holes CH with the minimum number of steps, contact processing shown in FIGS. 11 to 15 is performed.

For example, as shown in FIG. 11, first, a hard mask 70 is stacked on the insulator 36. The hard mask 70 may be, for example, silicon nitride. Thereafter, the contact holes CH1 to CH8 are formed by using the hard mask 70 as a mask by lithography and anisotropic etching by reactive ion etching (RIE). The contact holes CH1 to CH8 are formed at a depth reaching the upper surface of the insulator 35 at an uppermost stage of the stacked body Sla. At this stage, all the contact holes CH1 to CH8 are formed at the same depth. The depth of the contact hole CH8 is determined at this time point and is not etched anymore.

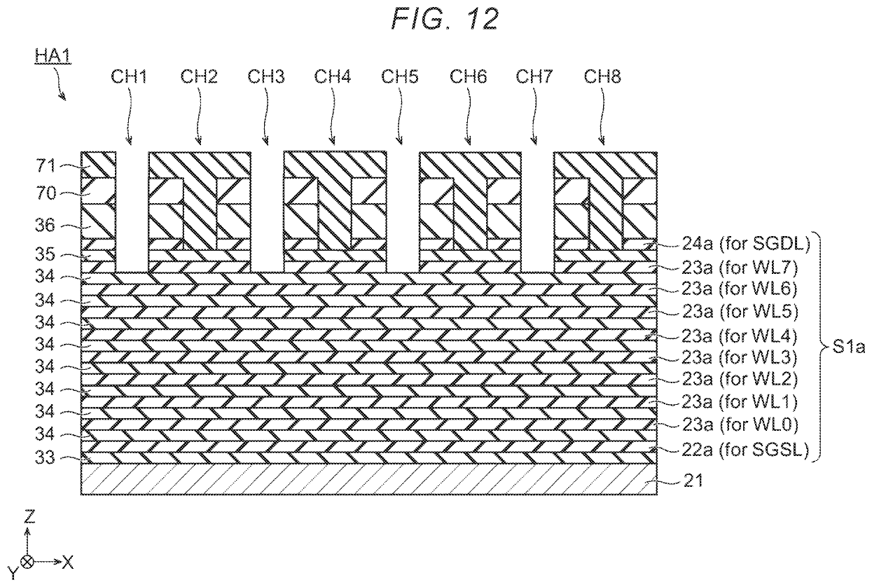

Next, as shown in FIG. 12, the contact holes CH2, CH4, CH6, and CH8 are covered with a resist film 71 and the bottom surfaces of the contact holes CH1, CH3, CH5, and CH7 are selectively etched by lithography and anisotropic etching via RIE. The contact holes CH1, CH3, CH5, and CH7 are etched up to the appropriate sacrificial film 23a as a next stage of the sacrificial film 24a, and the bottom surfaces of the contact holes CH1, CH3, CH5, and CH7 reach an upper surface of the insulator 34 as a next stage of the insulator 35. Accordingly, the contact holes CH1, CH3, CH5, and CH7 are etched up to the sacrificial film 23a (second sacrificial film from the uppermost stage) to be replaced with the word line WL7.

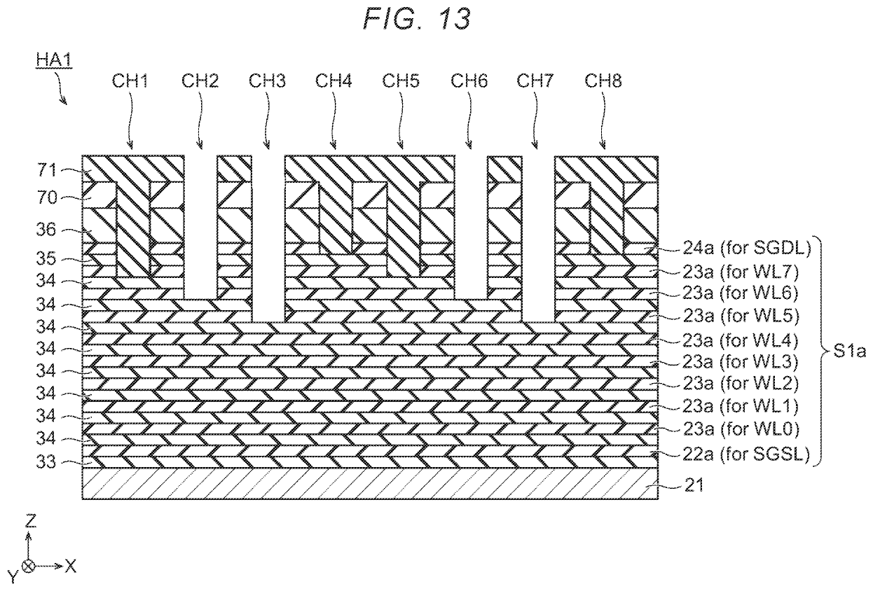

Next, as shown in FIG. 13, the contact holes CH1, CH4, CH5, and CH8 are covered with the resist film 71 and the bottom surfaces of the contact holes CH2, CH3, CH6, and CH7 are selectively etched by lithography and anisotropic etching via RIE. The contact holes CH2, CH3, CH6, and CH7 are etched up to the appropriate sacrificial film 23a as additional next stages while maintaining a step (difference in depth) therebetween, and the bottom surfaces of the contact holes CH2, CH3, CH6, and CH7 reach an upper surface of the insulator 34 as additional next stages. Therefore, the contact holes CH2 and CH6 are etched up to the sacrificial film 23a (third sacrificial film from the uppermost stage) to be replaced with the word line WL6, and the contact holes CH3 and CH7 are etched to the sacrificial film 23a (fourth sacrificial film from the uppermost stage) to be replaced with the word line WL5.

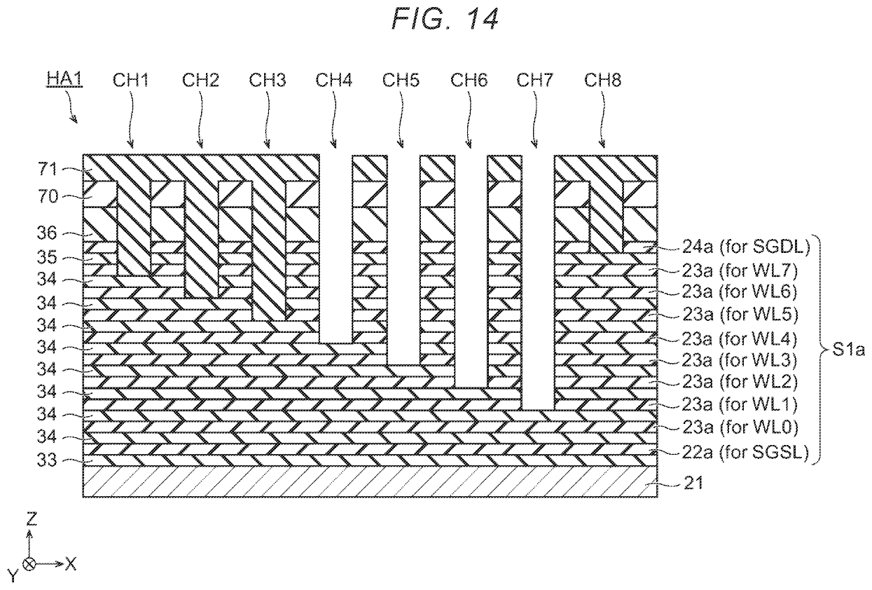

Next, as shown in FIG. 14, the contact holes CH1 to CH3 and CH8 are covered with the resist film 71 and the bottom surfaces of the contact holes CH4 to CH7 are selectively etched by lithography and anisotropic etching via RIE. The contact holes CH4 to CH7 are then etched up to the appropriate sacrificial film 23a as additional stages while maintaining the step (difference in depth) therebetween, and the bottom surfaces of the contact holes CH4 to CH7 reach an upper surface of the appropriate insulator 34 as a still further stage. Thus, the contact holes CH4 to CH7 are etched up to the appropriate sacrificial films 23a (fifth to eighth sacrificial films from the uppermost stage) to be replaced with the word lines WL4, WL3, WL2, and WL1, respectively.

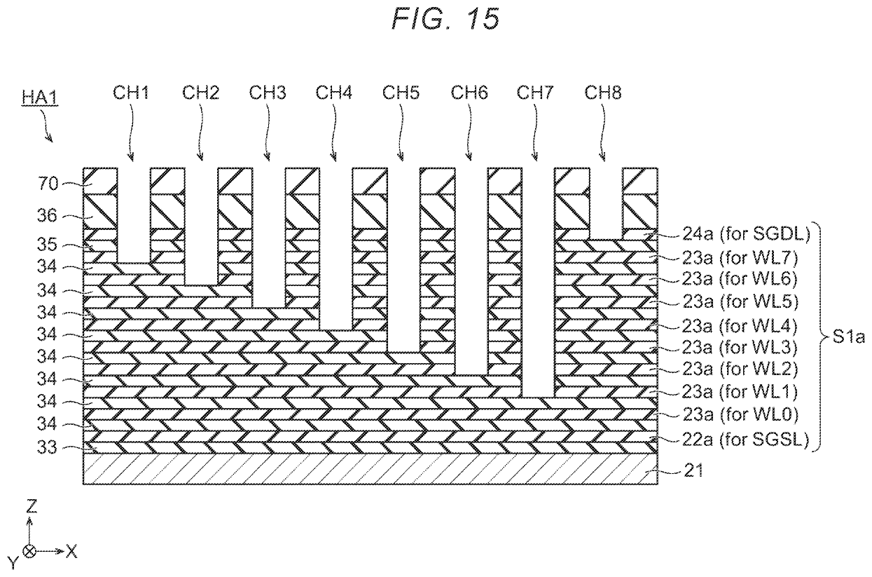

Next, as shown in FIG. 15, the resist film 71 and the hard mask 70 are removed. By the processes shown in FIGS. 11 to 15, the contact holes CH1 to CH8 extending in the z-axis direction in the stacked body Sla and respectively reaching the sacrificial films 22a to 24a or the insulators 33 to 36 are formed. Although not shown in FIG. 15, contact holes reaching the sacrificial film 23a to be replaced with the word line WL0 and the sacrificial film 22a to be replaced with the select gate line SGDL are also formed.

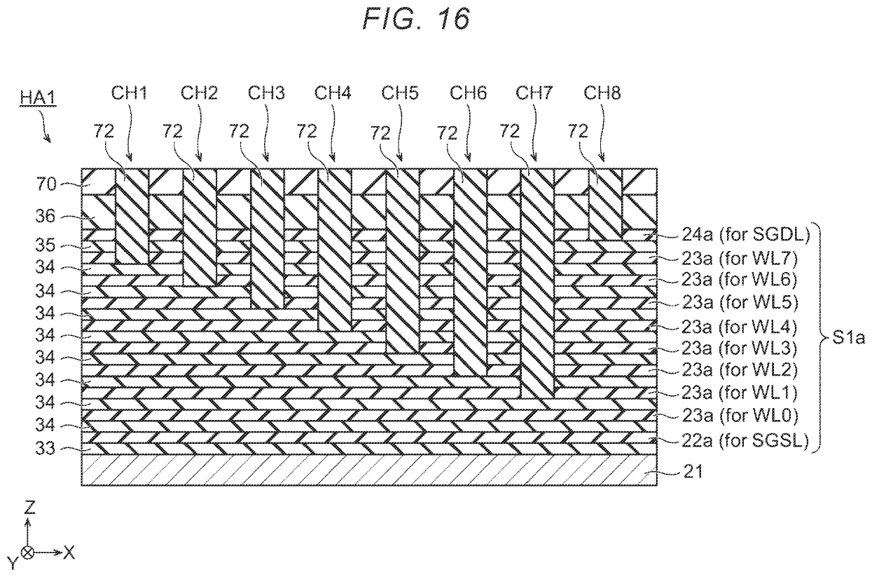

Next, as shown in FIG. 16, the contact holes CH are filled with sacrificial films 72. The sacrificial films 72 are an example of a second sacrificial film. The sacrificial films 72 are made of a material that can be selectively removed from the insulator 34, such as polysilicon or a silicon nitride film. Before filling the contact holes CH with the sacrificial films 72, the contact holes CH may be covered with the spacer 62 (see FIG. 7). The spacer 62 is an example of a second insulating film. The spacer 62 may be, for example, silicon oxide. Thereafter, the sacrificial films 72 are embedded inside the spacer 62. Next, the sacrificial films 72 deposited on the hard mask 70 are polished and etched back by chemical mechanical polishing (CMP). Accordingly, a structure shown in FIG. 16 is obtained.

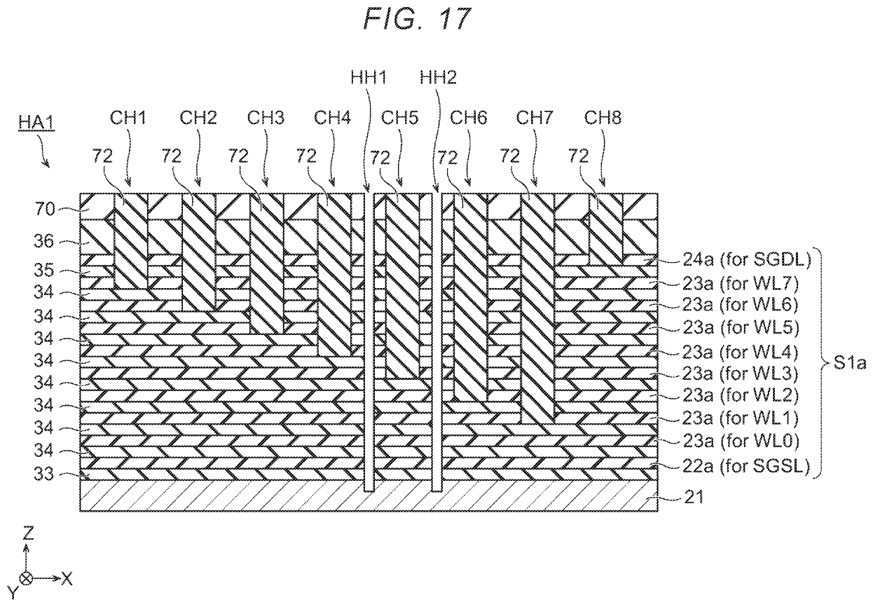

Next, as shown in FIG. 17, holes HH1 and HH2 are formed using lithography and RIE or the like. Hereinafter, the holes HH1 and HH2 may be collectively referred to as holes HH. The holes HH are an example of a second hole. The holes HH penetrate through the stacked body Sla in the z-axis direction, and are formed at a depth reaching an inside of the conductor 21. The hole HH1 is formed between the contact hole CH4 and the contact hole CH5, and the hole HH2 is formed between the contact hole CH5 and the contact hole CH6. The holes HH are formed separate from the contact holes CH. That is, in a plan view viewed from the z direction, the holes HH are separated from, rather than overlap, the contact holes CH. Any number of holes HH may be formed, and are formed between adjacent ones among the contact holes CH.

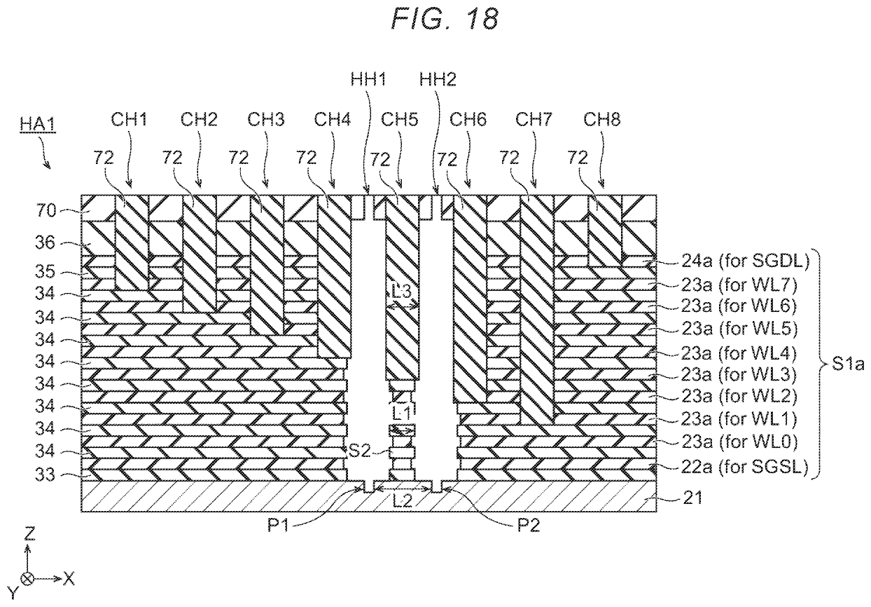

Next, as shown in FIG. 18, the insulators 33 to 36 and the sacrificial films 22a to 24a of the stacked body S1 are isotropically etched from inner walls of the holes HH1 and HH2 to expand inner diameters of the holes HH1 and HH2 by isotropic etching such as lithography and wet etching. Accordingly, the holes HH1 and HH2 come into contact with the sacrificial films 72 in the contact holes CH4 to CH6 to expose the sacrificial films 72. For example, the hole HH1 comes into contact with the sacrificial films 72 of the contact holes CH4 and CH5, and the hole HH2 comes into contact with the sacrificial films 72 of the contact holes CH5 and CH6. A stacked body S2 (portion S2) between the hole HH1 and the hole HH2 below the contact hole CH5 is also etched. Accordingly, the interval (width of the stacked body S2) L1 between the hole HH1 and the hole HH2 adjacent to each other in the stacked body S2 is narrower than the interval L2 between the hole HH1 and the hole HH2 in the arrow conductor 21. The interval L1 is narrower than the interval L3 (diameter of the contact hole CH5) between the holes HH1 and HH2 at a position of the contact hole CH5. That is, the width L1 of the stacked body S2 is narrower than the diameter L3 of the contact hole CH5.

As shown in FIG. 17, the holes HH1 and HH2 reach the conductor 21 before the expansion by the wet etching, and bite and protrude into the conductor 21. Therefore, as shown in FIG. 18, the holes HH1 and HH2 have the protruding portions P1 and P2 protruding into the conductor 21 after the expansion by the wet etching. An insulator is embedded in the protruding portions P1 and P2 below. Therefore, the protruding portions P1 and P2 remain as protruding portions made of the insulator unless the conductor 21 is removed.

During the formation of the holes HH1 and HH2, the insulators 33 to 36 may slightly protrude from outer edges (inner walls) of the holes HH1 and HH2 toward central axes of the holes HH1 and HH2. This is caused by a difference in etching rate between the insulators 33 to 36 and the sacrificial films 22a to 24a. Accordingly, even if the insulators 33 to 36 protrude into the holes HH1 and HH2, there is no problem because the insulator material is embedded in the holes HH1 and HH2 thereafter.

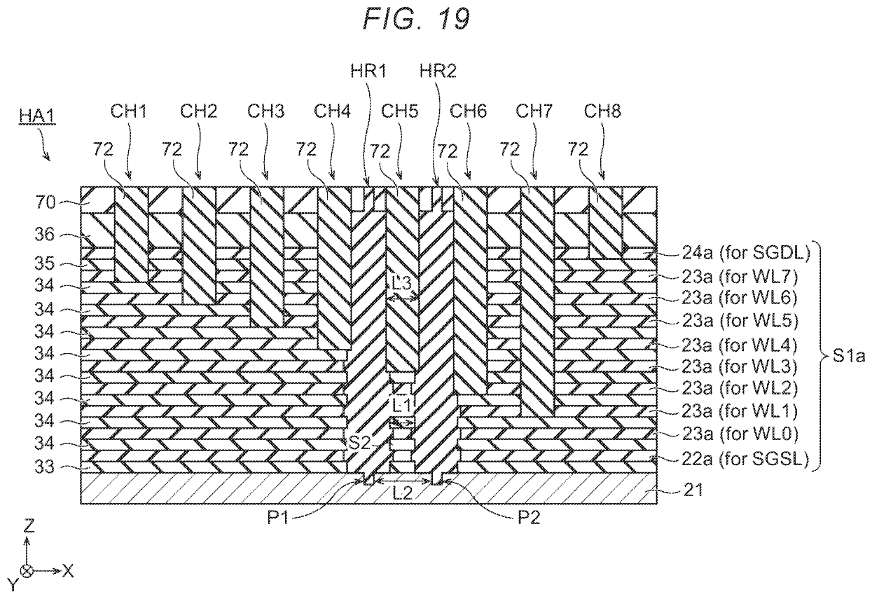

Next, as shown in FIG. 19, the holes HH1 and HH2 are filled with the insulator material. The insulator material may be, for example, silicon oxide. Accordingly, the support pillars HR1 and HR2 are formed.

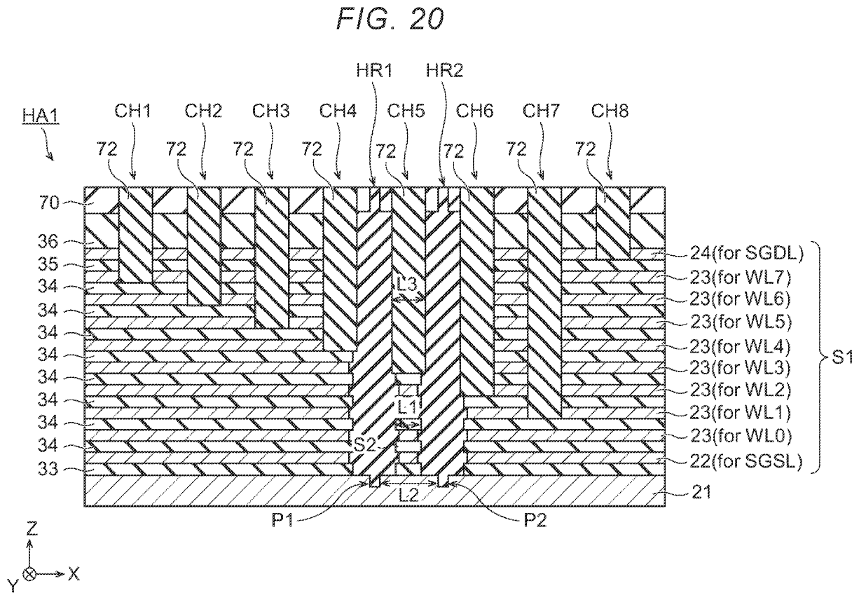

Next, as shown in FIG. 20, the sacrificial films 22a to 24a are replaced with the conductors 22 to 24 (replacement process). The word lines WL0 to WL7 and the select gate lines SGSL and SGDL are formed by the replacement process. In the replacement process, the sacrificial films 22a to 24a are selectively removed via the slits SLT (see FIGS. 4 and 5) by wet etching. Accordingly, a portion where the sacrificial films 22a to 24a are stacked temporarily becomes a space. The support pillars HR are provided to prevent the stacked body Sla from being depressed or deflected at this time.

In the first embodiment, the support pillars HR1 and HR2 are formed at the relatively wide interval L2 like the holes HH1 and HH2 shown in FIG. 17, and then extended like the holes HH1 and HH2 shown in FIG. 18 to be arranged at the relatively narrow interval L1. Accordingly, the holes HH or the support pillars HR can effectively prevent the depression or deflection of the stacked body Sla without interfering with the process of forming the contact holes CH.

Next, the space formed by removing the sacrificial films 22a to 24a is filled with tungsten (W) to form the conductors 22 to 24 (word lines WL and select gate lines SGDL and SGSL). During the filling of the tungsten, stress is applied to the stacked body S1, but since the support pillars HR according to the present embodiment are provided at a relatively short interval (distance L1), it is possible to prevent depression or deflection of the stacked body S1 and a short circuit between the conductors 22 to 24.

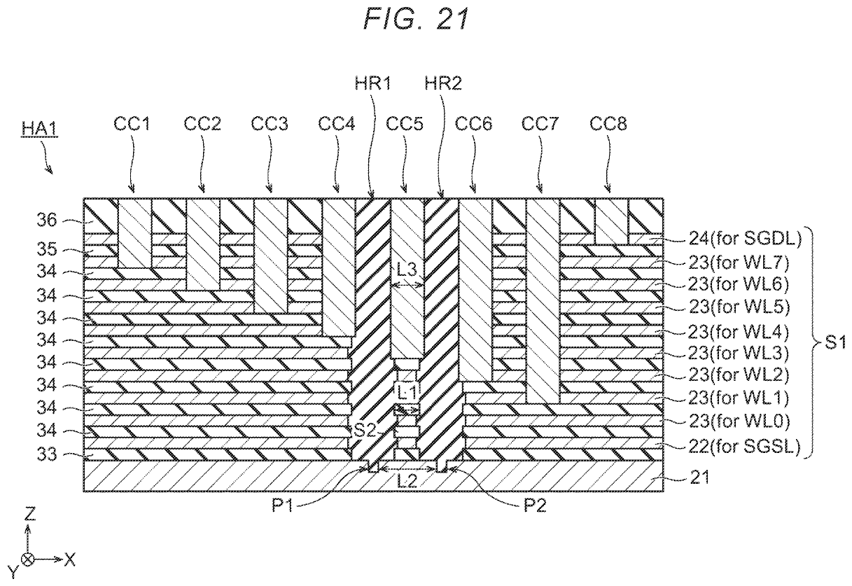

Next, as shown in FIG. 21, the sacrificial films 72 are removed using an etching technique, and the contact holes CH are filled with the conductor to form the contact plugs CC. When the spacer 62 is not formed on the inner wall of each of the contact holes CH in the process shown in FIG. 16, the spacer 62 is formed on the inner wall of the contact hole CH in the process shown in FIG. 21, and then the conductor fills inside the spacer 62 in the contact hole CH. Accordingly, the contact plugs CC are electrically connected to the corresponding conductors 23 (word lines WL), and are electrically separated from the other conductors 23 (word lines WL). That is, the spacer 62 can prevent a short circuit between the conductors 23 via the contact plugs CC.

Thereafter, a multilevel wiring structure or the like is formed on the insulator 36. A semiconductor wafer formed in this manner can be bonded to another semiconductor wafer on which a complementary metal oxide semiconductor (CMOS) circuit or the like is formed such as shown in FIG. 24. Thereafter, the semiconductor memory device 100 is obtained by a singularizing method such as dicing of the bonded wafers.

According to the above manufacturing method, it is not required to simultaneously process the stacked body S1 and the support pillars HR in the process of forming the contact holes CH of the contact plugs CC. This is because, during the formation of the contact holes CH, the interval L2 between the holes HH of the support pillars HR is wider than the diameter L3 of each of the contact holes CH, and the contact holes CH and the holes HH of the support pillars HR do not overlap. Accordingly, as described above, it is possible to prevent the generation of a void or a protruding portion in the bottom portion of the contact hole CH.

Although the interval L2 between the holes HH of the support pillars HR is relatively wide initially, the holes HH are expanded by wet etching, and the interval between the adjacent holes HH becomes the interval L1 or L3 narrower than the interval L2. In the plan view viewed from the z direction, an outer periphery of the contact hole CH overlaps a part of an outer periphery of the hole HH of each of the support pillars HR. Accordingly, an outer edge of the contact hole CH protrudes from an outer edge of the support pillar HR toward the central axis of the support pillar HR. Accordingly, in the replacement process during the formation of the conductors 22 to 24, the support pillars HR can reliably support the stacked body S1 and prevent the stacked body S1 from depression or deflection.

### Second Embodiment

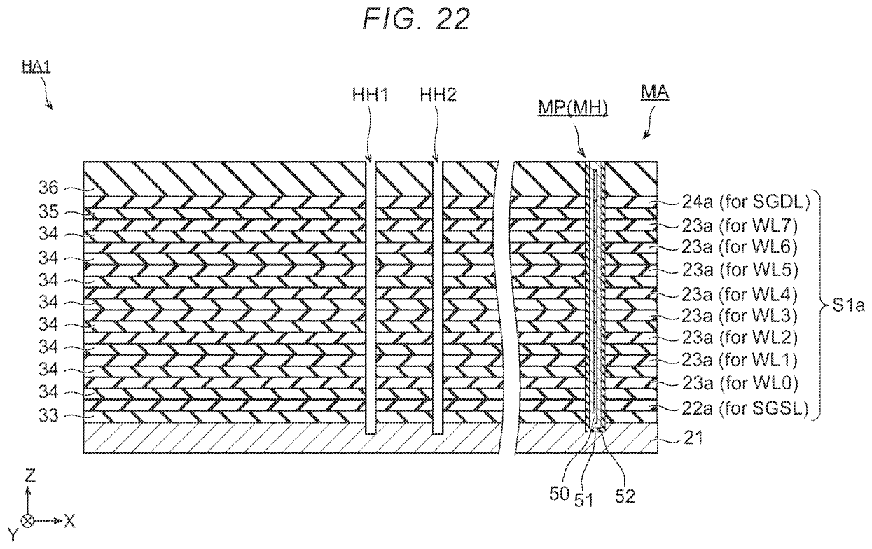

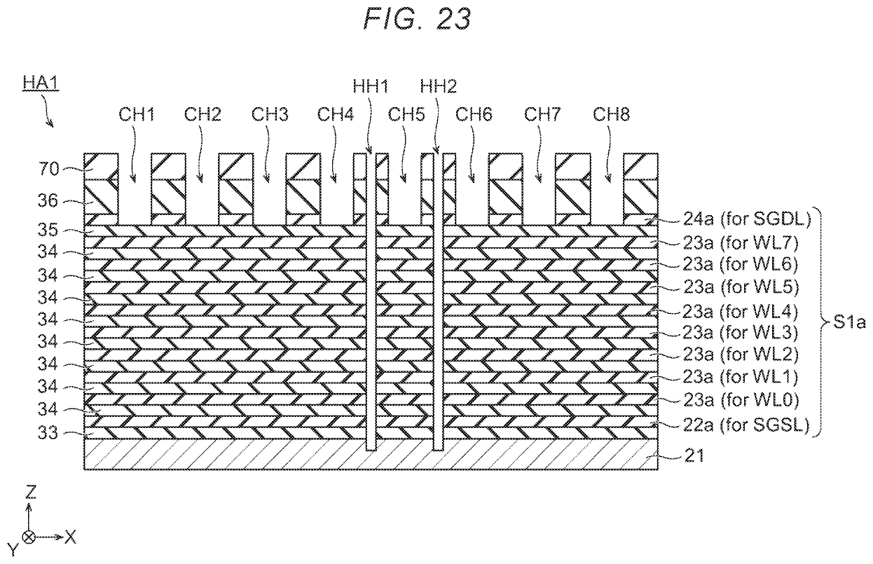

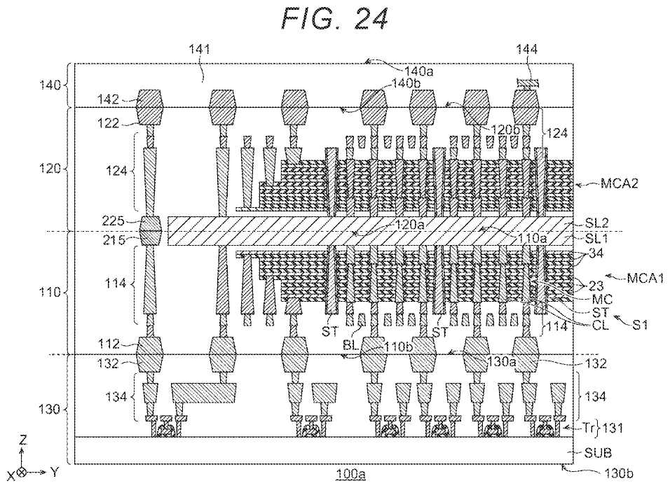

FIGS. 22 and 23 are cross-sectional views for explaining an example of a manufacturing method for a semiconductor memory device according to the second embodiment.

In the second embodiment, the holes HH before the expansion described for FIG. 17 are formed before the formation of the contact holes CH. That is, the process of forming the support pillars HR shown in FIG. 17 is performed before the process of forming the contact holes CH shown in FIG. 11.

For example, after the process described with reference to FIG. 10 has been performed, the holes HH1 and HH2 are formed as shown in FIG. 22. Next, after the process described with reference to FIG. 11 has been performed, the structure shown in FIG. 23 is obtained. The holes HH1 and HH2 are embedded with resist films in a lithography process and are thus not etch processed at this time.

Thereafter, the processing of the contact holes CH described with reference to FIGS. 12 to 17 is performed. The holes HH1 and HH2 are not processed until the process shown in

FIG. 17.

Next, in the process described with reference to FIG. 18, the holes HH1 and HH2 are expanded by wet etching. Thereafter, the semiconductor memory device 100 is formed through the same processes as that according to the first embodiment. Unless otherwise noted, the processes according to the second embodiment may be the same as the corresponding processes in the first embodiment. Likewise, the configuration of the semiconductor memory device according to the second embodiment may be the same as that according to the first embodiment. Therefore, the second embodiment can achieve the same effect as that according to the first embodiment.

### Bonding of Semiconductor Wafers

FIG. 24 is a cross-sectional view showing a detailed configuration example of a memory 100a. The memory 100a is an example of the semiconductor memory device 100. The memory 100a includes memory cell array layers 110 and 120 and a control circuit layer 130.

The memory cell array layer 110 and the memory cell array layer 120 are bonded at a first surface 110a and a third surface 120a. Source layers SL1 and SL2 are bonded at a bonding surface between the memory cell array layer 110 and the memory cell array layer 120. Accordingly, the source layers SL1 and SL2 function as an integrated common source layer SL1, SL2. Memory cell arrays MCA1 and MCA2 are electrically connected to the common source layer SL1, SL2.

A pad 215 of the memory cell array layer 110 and a pad 225 of the memory cell array layer 120 are bonded at the bonding surface between the memory cell array layer 110 and the memory cell array layer 120. The pad 215 may be electrically connected to any semiconductor element of the control circuit layer 130, such as transistors Tr, via multilevel wiring layers 114 and pads 112 of the memory cell array layer 110, and the like.

The memory cell array layer 110 and the control circuit layer 130 are bonded at a second surface 110b and a fifth surface 130a. The pads 112 of the memory cell array layer 110 and pads 132 of the control circuit layer 130 are bonded at a bonding surface between the memory cell array layer 110 and the control circuit layer 130. The pads 132 are electrically connected to the semiconductor elements of the control circuit layer 130, such as the transistors Tr, via multilevel wiring layers 134.

The memory cell array layer 120 and a multilevel wiring layer 140 are bonded at a fourth surface 120b and an eighth surface 140b. The pads 122 of the memory cell array layer 120 and pads 142 of the multilevel wiring layer 140 are bonded at a bonding surface between the memory cell array layer 120 and the multilevel wiring layer 140. The pads 142 can be freely connected to each other electrically via a wiring 144, and are electrically connected to the memory cell array MCA2 via the pads 122 and multilayer wiring layers 124 of the memory cell array layer 120.

Accordingly, the memory cell array MCA1 of the memory cell array layer 110 is electrically connected to a CMOS circuit 131 of the control circuit layer 130 via the multilevel wiring layers 114 and 134 and the pads 112 and 132. The memory cell array MCA2 of the memory cell array layer 120 is electrically connected to the CMOS circuit 131 of the control circuit layer 130 via the multilevel wiring layers 140, 114, 124, and 134 and the pads 112, 122, 132, and 142.

Accordingly, the control circuit layer 130 is shared by the memory cell array layers 110 and 120, and can control both the memory cell arrays MCA1 and MCA2. The source layers SL1 and SL2 may also be electrically connected to the CMOS circuit 131 via the multilevel wiring layers 114 and the like, and connected to an external power supply or the like via the multilevel wiring layers 114, 124, 134, and 140. Accordingly, a source voltage from the outside can be transmitted to the source layers SL1 and SL2.

The memory cell arrays MCA1 and MCA2 may basically have the same configuration. Therefore, only a configuration of the memory cell array MCA1 will be described below. The memory cell array MCA1 includes a stacked body S1, pillars CL, and slits ST.

The stacked body S1 is obtained by alternately stacking a plurality of electrode films 23 and a plurality of insulating films 34 along the Z-direction. The stacked body S1 constitutes a memory cell array. Examples of the electrode films 23 include, for example, a conductive metal such as tungsten. Examples of the insulating films 34 include, for example, an insulating film such as a silicon oxide film. The insulating films 34 insulate the electrode films 23 from each other. That is, the plurality of electrode films 23 are stacked in a mutually insulated state. Any number of electrode films 23 and insulating films 34 may be stacked. The insulating films 34 may be, for example, porous insulating films or air gaps.

One or more electrode films 23 at an upper end and a lower end of the stacked body S1 in the Z-direction function as a source-side select gate SGS and a drain-side select gate SGD, respectively. The electrode films 23 between the source-side select gate SGS and the drain-side select gate SGD function as the word lines WL. The word lines WL are gate electrodes of memory cells MC. The drain-side select gate SGD is a gate electrode of a drain-side select transistor. The source-side select gate SGS is provided in an upper region of the stacked body S1. The drain-side select gate SGD is provided in a lower region of the stacked body S1. The upper region refers to a region of the stacked body S1 closer to the control circuit layer 130, and the lower region refers to a region of the stacked body S1 closer to the source layers SL1 and SL2.

The memory cell array MCA1 includes a plurality of memory cells MC connected in series between a source-side select transistor and the drain-side select transistor. A structure in which the source-side select transistor, the memory cells MC, and the drain-side select transistor are connected in series is called a “memory string” or a “NAND string”. The memory string is connected to the bit lines BL via, for example, the multilevel wiring layers 114. The bit line BL is a wiring provided below the stacked body S1 and extending in the X direction.

The stacked body S1 is provided with a plurality of pillars CL. The pillars CL extend to penetrate through the stacked body S1 in a stacking direction of the stacked body in the stacked body S1 (Z-direction), and are provided from the multilevel wiring layers 114 connected to the bit lines BL to the source layer SL1. Internal structures of the pillars CL are as described below. In the present embodiment, the pillars CL have a high aspect ratio, and thus are formed in two stages in the Z direction. However, no problem necessarily occurs even if the pillars CL have just one stage.

A plurality of slits ST are provided in the stacked body S1. The slits ST extend in the X direction and penetrate the stacked body S1 in the stacking direction of the stacked body S1 (Z direction). Each of the slits ST is filled with an insulating film such as a silicon oxide film, and the insulating film is formed in a plate-like shape. The slit ST electrically separates the electrode films 23 of the stacked body S1. The slits ST may be a wiring having an insulating film provided on a side wall and a conductive film provided inside the insulating film. Accordingly, the slit ST can also function as a wiring electrically connected to the source layers SL1 and SL2 while electrically insulating the electrode films 23 of the stacked body S1.

The source layers SL1 and SL2 are provided on the stacked body S1. Examples of the source layers SL1 and SL2 include doped polysilicon and low-resistance metal materials such as copper, aluminum, and tungsten.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device, comprising:
a first film;
a first stacked body on the first film, the first stacked body including first insulating films and first conductive films alternately stacked in a first direction;
a first pillar extending in the first direction in the first stacked body, the first pillar including a first semiconductor portion and a first insulator portion on an outer peripheral surface of the first semiconductor portion;
a plurality of second pillars extending in the first direction in the first stacked body and reaching the first film, the second pillars each comprising an insulator material and having a bottom surface with a protrusion part protruding into the first film; and
a third pillar extending in the first direction in the first stacked body between adjacent ones of the second pillars, the third pillar comprising a conductor material that is electrically connected to one of the first conductive films of the first stacked body.

2. The semiconductor memory device according to claim 1, wherein the second pillars and the third pillar are in contact with each other.

3. The semiconductor memory device according to claim 2, wherein, in a plan view viewed from the first direction, the third pillar has a substantially circular shape, and the second pillars have a substantially circular shape with an arc part or a plurality of arc parts cut out.

4. The semiconductor memory device according to claim 1, wherein the second pillars protrude from an outer edge of the third pillar toward a center of the third pillar at a height position between the third pillar and the first film.

5. The semiconductor memory device according to claim 4, wherein the second pillars and the third pillar partially overlap each other in a plan view viewed from the first direction.

6. The semiconductor memory device according to claim 5, wherein, in a plan view viewed from the first direction, the third pillar has a substantially circular shape, and the second pillars have a substantially circular shape with an arc part or a plurality of arc parts cut out.

7. The semiconductor memory device according to claim 1, wherein the first pillar is a memory pillar.

8. The semiconductor memory device according to claim 1, wherein the plurality of second pillars are disposed in a lead-out region that is adjacent to a memory array region.

9. The semiconductor memory device according to claim 8, wherein the third pillar is a contact plug.

10. A semiconductor memory device, comprising:
a first film;
a first stacked body on the first film, the first stacked body including first insulating films and first conductive films alternately stacked in a first direction;
a first pillar extending in the first direction in the first stacked body, the first pillar including a first semiconductor portion and a first insulator portion on an outer peripheral surface of the first semiconductor portion;
a plurality of second pillars extending in the first direction in the first stacked body and reaching the first film; and
a third pillar extending in the first direction in the first stacked body between adjacent ones of second pillars, the third pillar comprising a conductor material that is electrically connected to one of the first conductive films of the stacked body, wherein
at least some of the first insulating films of the first stacked body protrude into from a side surface of at least one of second pillars toward a center of the second pillar.

11. The semiconductor memory device according to claim 10, wherein the second pillars each have a bottom surface with a protrusion part protruding into the first film.

12. The semiconductor memory device according to claim 10, wherein the second pillars and the third pillar are in contact with each other.

13. The semiconductor memory device according to claim 12, wherein, in a plan view viewed from the first direction, the third pillar has a substantially circular shape, and the second pillars have a substantially circular shape with an arc part or a plurality of arc parts cut out.

14. The semiconductor memory device according to claim 10, wherein the second pillars protrude from an outer edge of the third pillar toward a center of the third pillar at height position between the third pillar and the first film.

15. The semiconductor memory device according to claim 14, wherein the second pillars and the third pillar partially overlap each other in a plan view viewed from the first direction.

16. The semiconductor memory device according to claim 15, wherein, in the plan view viewed from the first direction, the third pillar has a substantially circular shape, and the second pillars have a substantially circular shape with an arc part or a plurality of arc parts cut out.

17. The semiconductor memory device according to claim 10, wherein the first pillar is a memory pillar.

18. The semiconductor memory device according to claim 10, wherein the plurality of second pillars are disposed in a lead-out region that is adjacent to a memory array region.

19. A manufacturing method for a semiconductor memory device, the method comprising:
forming a first stacked body by alternately stacking first insulating films and first sacrificial films in a first direction on a material film;
forming a first pillar extending in the first direction in the first stacked body, the first pillar including a first semiconductor portion and a first insulator portion provided on an outer peripheral surface of the first semiconductor portion;
forming a first hole extending in the first direction in the first stacked body and reaching one of the first insulating films or the first sacrificial films;
filling the first hole with a second sacrificial film;
forming, at a position separated from the first hole, a second hole penetrating the first stacked body in the first direction and reaching the material film;
increasing a diameter of the second hole by isotropic etching on an inner side surface of the second hole;
forming a second pillar by filling the second hole with an insulator;
replacing the first sacrificial films with first conductive films; and
forming a third pillar by replacing the second sacrificial film with a conductor.

20. The method according to claim 19, wherein
the second hole is connected to the first hole in the etching of the inner side surface of the second hole, and
the first stacked body between the second sacrificial film and the material film is etched from an outer edge of the first hole toward a center of the first hole.
